(19) United States
(12) Patent Application Publication
(10) Pub. No.: US 2007/0202680 A1
(43) Pub. Date: Aug. 30, 2007

(54) Semiconductor packaging method

(76) Inventor: Aminuddin Ismail, Selangor Darul Ehsan (MY)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/365,120

(22) Filed: Feb. 28, 2006

(51) Int. Cl. H01L 21/44

(52) U.S. Cl. 438/612

(57) ABSTRACT

A method of packaging one or more semiconductor dice (10) includes providing a heat spreader (12) and attaching a first semiconductor die (10) to the heat spreader (12). A first set of bumps (14) is formed on respective die pads on a top surface (16) of the first die (10) and at least a second set of bumps (18) is formed on the first set of bumps (14) such that stacks of bumps (20) are formed on the top surface (16) of the first die (10). A molding process is performed such that a mold compound (24) is formed over the one or more dice (10), the stacks of bumps (20) and a portion of the heat spreader (12), which forms a semiconductor package (26).

### BACKGROUND OF THE INVENTION

The present invention relates to the packaging of integrated circuits (ICs) and more particularly to a method of packaging one or more semiconductor dice with a heat spreader.

Ball Grid Array (BGA) packages are leadless, surface-mountable packages that utilise arrays of metal spheres to provide external electrical interconnection to the semiconductor dice encapsulated therein. Because of the numerous advantages that BGA packages have over conventional leaded packages, many different approaches to the manufacture of BGA packages have been devised. However, many of these tend to be too expensive or complex to be implemented in high-volume manufacturing applications. Furthermore, as more functions are located on a chip, the chip generates quite a lot of heat during operation. Thus, a need exists for a simple and inexpensive method of forming a BGA package that can dissipate the heat generated by the die.

Accordingly, it is an object of the present invention to provide a simple and inexpensive method of packaging one or more semiconductor dice.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is an enlarged cross-sectional view of a semiconductor die attached to a heat spreader, the die having stacks of bumps formed thereon in accordance with an embodiment of the present invention;

FIG. 2 is an enlarged cross-sectional view of the die and the bumps of FIG. 1 encapsulated by a mold compound in accordance with an embodiment of the present invention;

FIG. 3 is an enlarged cross-sectional view of the semiconductor package of FIG. 2 having a plurality of conductive balls attached thereto;

FIG. 4 is an enlarged top plan view of the semiconductor package of FIG. 3;

FIG. 5 is an enlarged cross-sectional view of a first and a second semiconductor die stacked on a heat spreader in accordance with another embodiment of the present invention;

FIG. 6 is an enlarged cross-sectional view of stacks of bumps formed on the first die of FIG. 5 and a set of bumps formed on the second die of FIG. 5;

FIG. 7 is an enlarged cross-sectional view of the dice and the bumps of FIG. 6 encapsulated by a mold compound;

FIG. 8 is an enlarged cross-sectional view of the semiconductor package of FIG. 7 having a plurality of conductive balls attached thereto; and

FIG. 9 is an enlarged cross-sectional view of a plurality of dice being packaged simultaneously in accordance with an embodiment of the present invention.

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention. In the drawings, like numerals are used to indicate like elements throughout.

The present invention provides a method of packaging one or more semiconductor dice including the steps of providing a heat spreader and attaching a first semiconductor die to the heat spreader. A first set of bumps is formed on respective die pads on a top surface of the first die and at least a second set of bumps is formed on the first set of bumps such that stacks of bumps are formed on the top surface of the first die. A molding process is performed such that a mold compound is formed over the one or more dice, the bumps and a portion of the heat spreader, thereby forming a semiconductor package.

The present invention also provides a method of packaging one or more semiconductor dice including the steps of providing a heat spreader and attaching a first semiconductor die to the heat spreader. A second semiconductor die is attached to a top surface of the first die. A first set of bumps is formed on respective die pads on the top surface of the first die and at least a second set of bumps is formed on the first set of bumps such that stacks of bumps are formed on the top surface of the first die. At least one set of bumps is formed on respective die pads on a top surface of the second die. A molding process is performed such that a mold compound is formed over the one or more dice, the bumps and a portion of the heat spreader, thereby forming a semiconductor package.

The present invention also provides a method of forming a plurality of semiconductor packages simultaneously. A sheet of heat spreader material is provided and a plurality of dice is attached to the heat spreader material at predetermined spaced locations. Stacks of bumps are formed on the die bonding pads of the dice. A molding process is performed such that a mold compound is formed over all of the dice, the bumps and a portion of the sheet of heat spreader material, thus forming an array of semiconductor packages. A singulation process is performed on the array, thereby forming a plurality of semiconductor packages.

The present invention further provides a semiconductor package including one or more semiconductor dice and a heat spreader. A first semiconductor die is attached to the heat spreader. A first set of bumps is formed on respective die pads on a top surface of the first die and at least a second set of bumps is formed on the first set of bumps such that stacks of bumps are formed on the top surface of the first die. A mold compound is formed over the one or more dice, the bumps and a portion of the heat spreader. Portions of the top-most bumps are exposed.

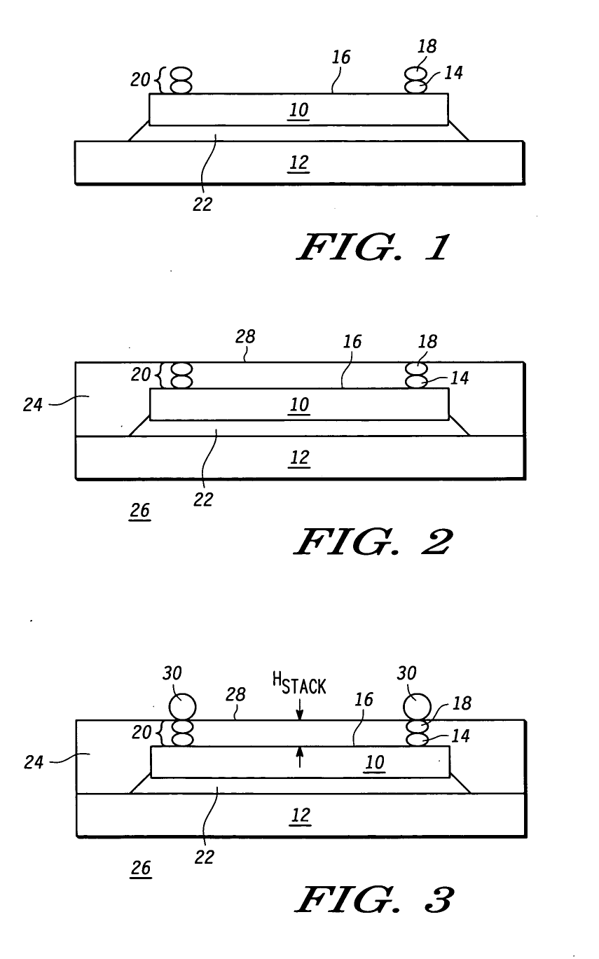

FIGS. 1 to 3 are enlarged cross-sectional views that illustrate a method of packaging a semiconductor die in accordance with an embodiment of the present invention.

Referring now to FIG. 1, a semiconductor die 10 is attached to a heat spreader 12 as shown. A first set of bumps 14 is formed on respective die pads (not shown) on a top surface 16 of the die 10 and at least a second set of bumps 18 is formed on the first set of bumps 14 such that stacks of bumps 20 are formed on the top surface 16 of the die 10.

The die 10 may be a processor, such as a digital signal processor (DSP), a special function circuit, such as a memory address generator, or a circuit that performs any other type of function. The die 10 is not limited to a particular technology such as CMOS, or derived from any particular wafer technology. However, as will be apparent to those of skill in the art, unbumped wafers can be used in the present invention. Further, the present invention can accommodate dice of various dimensions. A typical example is a memory die having a size of about 8.0 millimetres (mm) by 8.0 mm, and a thickness of about 15.0 mils. In this particular example, the die 10 has a die pad pitch of at least about 3 mm. Nonetheless, it will be understood by those of skill in the art that the present invention is not limited to dice having a 3 mm pad pitch. The heat spreader 12 is made of a thermally conductive material such as, for example, copper or aluminium. The die 10 is attached to the heat spreader 12 using a conductive die attach material 22. The die attach material 22 may be an adhesive such as, for example, an epoxy material or a eutectic alloy such as, for example, a solder material. The bumps 14 and 18 may be formed by a wire bonding process, like ball bonding, using wires made of gold (Au) or other electrically conductive materials as are known in the art and commercially available.

Referring now to FIG. 2, a molding process is performed such that a mold compound 24 is formed over the die 10, the bumps 14 and 18 and a portion of the heat spreader 12, thereby forming a semiconductor package 26. A well known molding process such as, for example, an injection molding process may be used to perform the encapsulation. The mold compound 24 may comprise well known commercially available molding materials such as plastic or epoxy. As shown in FIG. 2, portions of the top-most bumps, in this particular example, the second set of bumps 18, are exposed to provide external electrical connection to the encapsulated die 10. The exposed portions of the top-most bumps 18 are substantially co-planar. If necessary to ensure good electrical connection, the top-most bumps 18 may be exposed by grinding or polishing a surface 28 of the semiconductor package 26.

Referring now to FIG. 3, conductive balls 30 are attached to the exposed portions of the top-most bumps 18 as shown. The conductive balls 30 may be controlled collapse chip carrier connection (C5) solder balls that are attached to the exposed portions of the top-most bumps 18 using known solder ball attach processes.

Although FIGS. 1 to 3 show only two (2) bumps 14 and 18 in each stack 20, it will be understood that each stack 20 may comprise fewer or more bumps in alternative embodiments. In one embodiment, each stack of bumps 20 may have a height H_{stack} of at least about 8 mils to facilitate flow of the mold compound 24 between the stacks 20 during the molding process. In another embodiment, each of the stacks 20 may comprise less than six (6) bumps to prevent crack formation in the bottom-most bumps (i.e. the first set of bumps 14) and to avoid differences in the size of the exposed portions of the top-most bumps 18, shifting of the exposed portions of the top-most bumps 18 from the desired locations on the surface 28 of the package 26, the bumps peeling off one another, and co-planarity issues.

Referring now to FIG. 4, an enlarged top plan view of the semiconductor package 26 with the conductive balls 30 of FIG. 3 is shown. As can be seen, the conductive balls 30 in this particular example are in a perimeter array configuration. However, those of skill in the art will understand that the present invention is not limited to perimeter array packages such as the one shown in FIG. 4. The present invention may, for example, be applied to area array packages as well. In one embodiment, the semiconductor package 26 has a ball pitch P_{ball} of greater than about 300 microns (μm). Nonetheless, it will be understood by those of skill in the art that the present invention is not limited to semiconductor packages with a particular ball pitch P_{ball}.

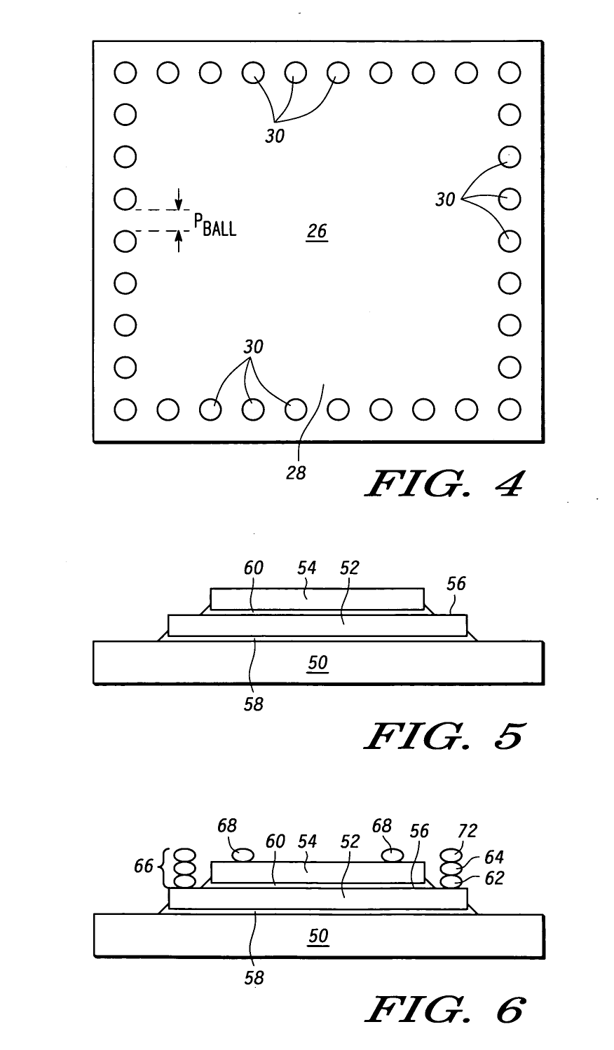

FIGS. 5 to 8 are enlarged cross-sectional views that illustrate a method of making a stacked die package in accordance with another embodiment of the present invention.

Referring now to FIG. 5, a heat spreader 50 is provided as shown. A first semiconductor die 52 is attached to the heat spreader 50 and a second semiconductor die 54 is attached to a top surface 56 of the first die 52.

Like the heat spreader 12, the heat spreader 50 is made of a thermally conductive material such as, for example, copper or aluminium. The first and second dice 52 and 54 may be processors, such as digital signal processors (DSP), special function circuits, such as memory address generators, or circuits that perform any other type of function. Like the die 10, the first and second dice 52 and 54 are not limited to a particular technology such as CMOS, or derived from any particular wafer technology. Further, the present invention can accommodate dice of various sizes, as will be understood by those of skill in the art. A typical example is a bottom die having a size of about 8.0 mm by 8.0 mm and a top die having a size of about 5.0 mm by 5.0 mm. As shown in FIG. 5, the second die 54 is smaller than the first die 52. In a preferred embodiment, each of the first and second die 52 and 54 has a thickness of less than about 7.0 mil so that the stack up height of the dice 52 and 54 is not greater than about 0.5 mm. In one embodiment, each of the first and second die 52 and 54 has a die pad pitch of at least about 3 mm. Nonetheless, as previously discussed, it will be understood that the present invention is not limited to dice having a particular die pad pitch. The first die 52 is attached to the heat spreader 50 using a first die attach material 58, while the second die 54 is attached to the top surface 56 of the first die 52 using a second die attach material 60. The first and second die attach materials 58 and 60 may be well known commercially available conductive die attach materials such as epoxy or solder.

Referring now to FIG. 6, a first set of bumps 62 is formed on respective die pads (not shown) on the top surface 56 of the first die 52 and at least a second set of bumps 64 is formed on the first set of bumps 62 such that stacks of bumps 66 are formed on the top surface 56 of the first die 52. At least a set of bumps 68 is formed on respective die pads (not shown) on a top surface 70 of the second die 54. Although only one (1) set of bumps 68 is formed on the second die 54 in this particular embodiment, it will be understood by those of skill in the art that additional sets of bumps may be formed in alternative embodiments. The number of bumps in each stack 66 is dependent on the height of the second die 54 and the number of sets of bumps formed on the second die 54. In this particular embodiment, the stacks 66 comprise three (3) sets of bumps 62, 64 and 72 so that the tops of the stacks 66 are substantially co-planar with the tops of the bumps 68. The bumps 62, 64, 68 and 72 may be formed by a ball wire bonding process using wires made of gold (Au) or other electrically conductive materials as are known in the art and commercially available. The exposed portions of the top-most bumps 68 and 72 are co-planar.

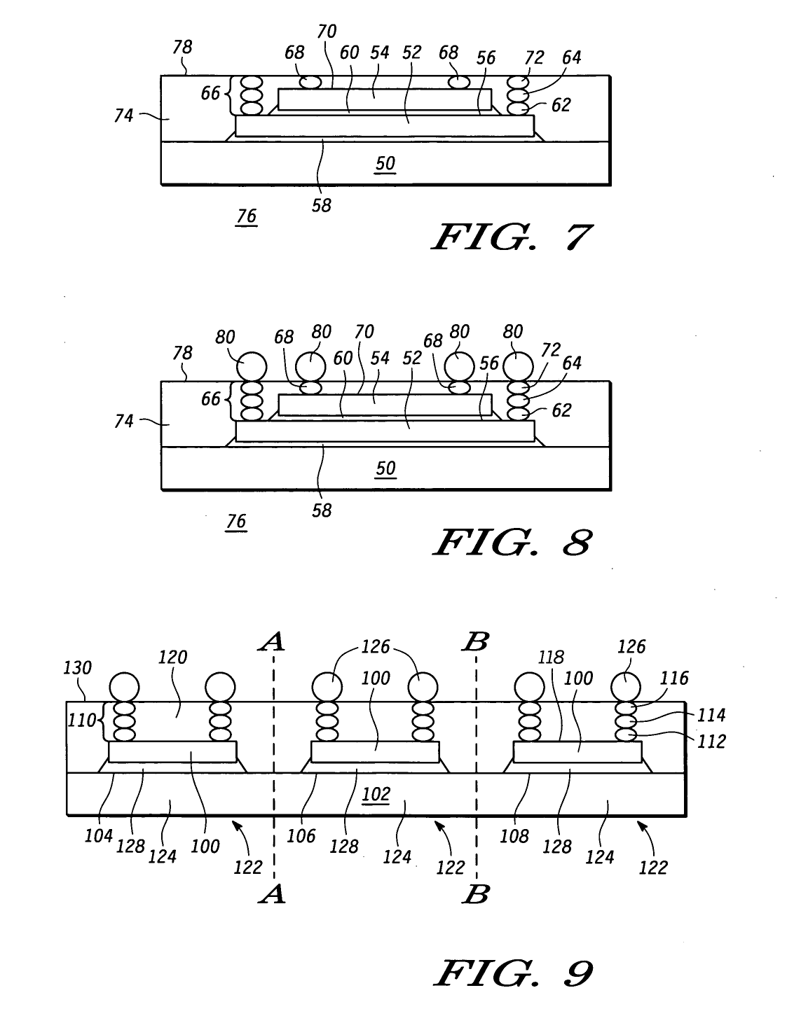

Referring now to FIG. 7, a molding process is performed such that a mold compound 74 is formed over the first and second dice 52 and 54, the bumps 62, 64, 68 and 72 and a portion of the heat spreader 50, thereby forming a semiconductor package 76. A well known molding process such as, for example, an injection molding process may be used to perform the encapsulation. The mold compound 74 may comprise well known commercially available molding materials such as plastic or epoxy. As shown in FIG. 7, portions of the top-most bumps 68 and 72 are exposed to provide external electrical connection to the encapsulated first and second dice 52 and 54. The top-most bumps 68 and 72 may be exposed by grinding or polishing a surface 78 of the semiconductor package 76.

Referring now to FIG. 8, conductive balls 80 are attached to the exposed portions of the top-most bumps 68 and 72 as shown. The conductive balls 80 may be C5 solder balls and may be attached to the exposed portions of the top-most bumps 68 and 72 using known solder ball attach processes.

Although FIGS. 5 to 8 show only two (2) dice 52 and 54, it will be understood that more dice may be packaged with the present invention, depending on the size and thickness of the dice, and the required functionality of the resulting devices.

Referring now to FIG. 9, a plurality of semiconductor dice 100 being packaged simultaneously is shown. A heat spreader plate 102 is provided to which the dice 100 are attached at predetermined locations 104, 106 and 108. Respective stacks 110 of bumps 112, 114 and 116 are formed on die bonding pads (not shown) on a top surface 118 of the dice 100. As can be seen, the top-most bumps 116 of the stacks 110 are substantially co-planar. A molding process is performed such that a mold compound 120 is formed over the dice 100, the stacks of bumps 110 and a portion of the heat spreader plate 102. A singulating operation is performed along the vertical lines A-A and B-B to separate the dice 100 from each other, thereby forming a plurality of packaged semiconductor package devices 122. As can be seen from FIG. 9, the heat spreader plate 102 is singulated into a plurality of heat spreaders 124 for respective ones of the semiconductor packages 122. Conductive balls 126 may be attached to the exposed portions of the top-most bumps 116.

The heat spreader plate 102 may comprise a sheet of thermally conductive material such as, for example, copper or aluminium. In one embodiment, the heat spreader plate 102 has a thickness of about 1.0 mm. Like the die 10, the dice 100 are not limited to a particular technology such as CMOS, or derived from any particular wafer technology. Further, the present invention can accommodate dice of various dimensions. In this particular example, the dice 100 have a die pad pitch of at least about 3 mm. Nonetheless, it will be understood by those of skill in the art that the present invention is not limited to dice having a 3 mm pad pitch. The dice 100 are attached to the heat spreader plate 102 using a conductive die attach material 128. The die attach material 128 may be an adhesive such as, for example, an epoxy material or a eutectic alloy such as, for example, a solder material. Like the bumps 14 and 18 in the stacks 20, the bumps 112, 114 and 116 formed on the top surface 118 of the dice 100 may be formed by a wire bonding process, like ball bonding, using wires made of gold (Au) or other electrically conductive materials as are known in the art and commercially available.

A well known molding process such as, for example, an injection molding process may be used to perform the encapsulation. As previously mentioned, the mold compound 120 may comprise well known commercially available molding materials such as plastic or epoxy. As shown in FIG. 9, portions of the top-most bumps 116 are exposed to provide external electrical connection to the encapsulated dice 100. To ensure good electrical connection, the top-most bumps 116 may be exposed by grinding or polishing a surface 130 of the semiconductor packages 122. A well known singulation process such as, for example, saw singulation may be employed to separate the dice 100 from each other. The conductive balls 126 attached to the exposed portions of the top-most bumps 116 may be C5 solder balls like conductive balls 30 in FIG. 3. The conductive balls 126 may be attached to the exposed portions of the top-most bumps 116 using known solder ball attach processes. As will be understood by those of skill in the art, the conductive balls 126 may be attached to the exposed portions of the top-most bumps 116 before or after the singulating operation.

Although FIG. 9 shows only three (3) dice 120 being packaged simultaneously, it will be understood that more or fewer dice 100 may be attached to the heat spreader plate 102, depending on the size of the heat spreader plate 102 and the size of the dice 100. Similarly, although the stacks 110 show only three balls 112, 114 and 116, more or fewer balls may be used to form the stacks 110.

As is evident from the foregoing discussion, the present invention provides a simple and inexpensive method of packaging one or more semiconductor dice. The packaging process is simple and the packaging costs are low as the packaging method of the present invention requires few processing steps. Further, additional cost savings are achieved because the present invention does not require the use of lead frames, substrates or bumped dice.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. For example, although Ball Grid Array (BGA) packages have been described, other package types such as, for example, Land Grid Array (LGA) packages can also be formed with the present invention. It is understood, therefore, that this invention is not limited to the particular embodiments disclosed, but covers modifications within the spirit and scope of the present invention as defined by the appended claims.

1. A method of packaging a semiconductor die, comprising:
providing a heat spreader;
attaching a first semiconductor die to the heat spreader;
forming a first set of bumps on respective die pads on a first surface of the first die;
forming at least a second set of bumps on the first set of bumps such that stacks of bumps are formed on the first surface of the first die; and
performing a molding process, wherein a mold compound is formed over the first die, the bumps and a portion of the heat spreader, thereby forming a semiconductor package.

2. The method of packaging a semiconductor die of claim 1, wherein portions of the top-most bumps are exposed.

3. The method of packaging a semiconductor die of claim 2, further comprising attaching conductive balls to the exposed portions of the top-most bumps.

4. The method of packaging a semiconductor die of claim 2, wherein the top-most bumps are exposed by grinding a surface of the semiconductor package.

5. The method of packaging a semiconductor die of claim 1, further comprising:
attaching a second semiconductor die to the first surface of the first die, wherein the second die is smaller than the first die; and
forming at least a third set of bumps on respective die pads on a top surface of the second die.

6. The method of packaging a semiconductor die of claim 5, wherein the exposed portions of the top-most bumps are co-planar.

7. The method of packaging a semiconductor die of claim 1, wherein the bumps are formed by a wire bonding process.

8. The method of packaging a semiconductor die of claim 1, wherein each stack of bumps has a height of at least about 8 mils.

9. The method of packaging a semiconductor die of claim 1, wherein each stack comprises less than six bumps.

10. The method of packaging a semiconductor die of claim 1, wherein the die has a die pad pitch of at least about 3 mm.

11. The method of packaging a semiconductor die of claim 1, wherein the heat spreader is made of one of copper and aluminium.

12. The method of packaging a semiconductor die of claim 1, wherein the first die is attached to the heat spreader using one of a solder material and an epoxy material.

13. A method of forming a packaged semiconductor device, comprising:
providing a heat spreader;
attaching a first semiconductor die to the heat spreader;
attaching a second semiconductor die to a top surface of the first die;
forming a first set of bumps on respective die pads on the top surface of the first die;
forming at least a second set of bumps on the first set of bumps such that stacks of bumps are formed on the top surface of the first die;
forming at least a third set of bumps on respective die pads on a top surface of the second die; and
performing a molding process, wherein a mold compound is formed over the first and second dice, the bumps and a portion of the heat spreader, thereby forming a packaged semiconductor device.

14. The method of forming a packaged semiconductor device of claim 13, wherein portions of the top-most bumps are exposed, the method further comprising attaching conductive balls to the exposed portions of the top-most bumps.

15. The method of forming a packaged semiconductor device of claim 13, wherein the top-most bumps are exposed by grinding a surface of the semiconductor package.

16. The method of forming a packaged semiconductor device of claim 13, wherein the bumps are formed by a wire bonding process.

17. A method of forming a plurality of semiconductor devices, comprising the steps of:
providing a heat spreader plate;
attaching a plurality of semiconductor dice to predetermined locations of the heat spreader plate, wherein the dice have die bonding pads on a top surface thereof;
forming respective stacks of bumps on the die bonding pads of the semiconductor dice, wherein the top-most bumps of the stacks of bumps are substantially co-planar;
performing a molding process, wherein a mold compound is formed over the dice, the stacks of bumps and a portion of the heat spreader plate; and
performing a singulating operation to separate the dice from each other, thereby forming a plurality of packaged semiconductor package devices.

18. The method of forming a plurality of semiconductor devices of claim 17, wherein portions of the top-most bumps are exposed, further comprising the step of attaching conductive balls to the exposed portions of the top-most bumps.

19. The method of forming a plurality of semiconductor devices of claim 17, wherein the top-most bumps are exposed by grinding a surface of the semiconductor packages.

20. The method of forming a plurality of semiconductor devices of claim 17, wherein the stacks of bumps are formed by a wire bonding process.
